(19) United States
(12) Patent Application Publication
(10) Pub. No.: US 2005/0263795 A1
(43) Pub. Date: Dec. 1, 2005

(54) Semiconductor device having a channel layer and method of manufacturing the same

(76) Inventors: Jeong-Dong Choi, Gyeonggi-do (KR); Chang-Woo Oh, Gyeonggi-do (KR); Dong-Gun Park, Gyeonggi-do (KR); Dong-Won Kim, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/137,608

(22) Filed: May 24, 2005

(30) Foreign Application Priority Data
May 25, 2004 (KR) 2004-37470

(51) Int. Cl. H01L 29/76; H01L 21/335

(52) U.S. Cl. 257/213; 438/142

(57) ABSTRACT

In a method of forming a semiconductor device having an improved channel layer, the channel layer is formed on a surface of a semiconductor substrate and comprises a material of high carrier mobility such as silicon germanium (SiGe), germanium (Ge) and silicon carbide (SiC) using a selective epitaxial growth process. A gate insulation layer and a gate electrode are formed on the channel layer. Accordingly, a driving current of the semiconductor device increases to thereby improve operation characteristics.

### CROSS-REFERENCE TO RELATED APPLICATION

This application relies for priority upon Korean Patent Application No. 2004-37470 filed on May 25, 2004, the content of which is herein incorporated by reference in its entirety.

### BACKGROUND OF THE INVENTION

1. Field of the Invention

The present invention relates to a semiconductor device having a channel layer and a method of manufacturing the same. More particularly, the present invention relates to a semiconductor device such as a field effect transistor (FET) and a method of manufacturing the same.

2. Description of the Related Art

As semiconductor devices are highly integrated, an active region in which various conductive structures are positioned has been reduced in a size and a channel length of the MOS transistor in the active region has been also shortened. When the channel length is shortened, a voltage applied to a source or a drain of the MOS transistor has much more effect on an electrical field in a channel region, which is called as a short channel effect. In addition, when the size of the active region is reduced, a width of the channel of the MOS transistor is also reduced, thereby increasing a threshold voltage of the MOS transistor, which is called as a narrow channel effect or a narrow width effect.

Accordingly, recent research and development have been focused on reducing the size of a conductive structure in a semiconductor device without decreasing performance of the semiconductor devices. A vertical transistor such as a fin structure, a fully depleted lean-channel structure (hereinafter, referred to as DELTA structure) and a gate-all-around structure (hereinafter, referred to as GAA structure) are common examples.

For example, U.S. Pat. No. 6,413,802 discloses a fin structured MOS transistor, in which a plurality of thin channel fins is positioned between the source/drain regions and a gate electrode extends to a top surface and sidewall of the channels. The gate electrode is formed on both sidewalls of the channel fin, and the gate may be under control at both sidewalls thereof, thereby reducing the short channel effect. However, the fin structured MOS transistor is disadvantageous in that a plurality of channel fins is arranged in parallel along a width direction of the gate; thus the channel region and the source/drain regions are enlarged in the MOS transistor. Another drawback of the fin structured MOS transistor is that junction capacitance between the source and drain regions is increased as the channel number is increased.

A MOS transistor having the DELTA structure (DELTA MOS transistor) is disclosed in U.S. Pat. No. 4,996,574. In the DELTA MOS transistor, an active layer on which a channel is formed protrudes vertically with a predetermined width, and a gate electrode surrounds the protruded channel region. Thus, a protruded height corresponds to a width of the channel, and a protruded width corresponds to a thickness of the channel. Accordingly, both sides of the protruded portion are utilized as a channel in the MOS transistor. Thus the channel is twice a size of the conventional channel in a width, thereby preventing the narrow width effect. In addition, reducing the width of the protruded portion causes an overlap of two depletion areas formed at both side portions of the protruded portion, thereby improving channel conductivity.

However, the DELTA MOS transistor has disadvantages as follows. When the DELTA MOS transistor is formed on a bulk silicon substrate, the bulk silicon substrate is treated such that a portion thereof on which the channel region is to be formed is protruded initially and then is oxidized so that the protruded portion of the substrate is covered with an anti-oxidation layer. If the substrate is over-oxidized, a ridge portion of the substrate between the protruded portion and a non-protruded or an even portion is also oxidized with oxygen laterally diffused from the even portion that is not covered with the anti-oxidation layer, causing the channel on the protruded portion of the substrate to be separated from the even portion of the substrate. That is, an over-oxidation separates the channel from the bulk substrate, and reduces a thickness of the ridge portion of the substrate. In addition, a single-crystalline layer is damaged due to a stress during the over-oxidation process.

When the DELTA MOS transistor is formed on a silicon-on-insulator (SOI) substrate, the SOI layer on the substrate is etched away to thereby form a channel region having a narrow width. Therefore, in contrast to the bulk substrate, over-oxidation causes no problem when the SOI substrate is utilized. However, there is a problem that the channel width is limited by the thickness of the SOI layer. In particular, in case of a fully depletion type SOI substrate, the SOI thickness on the substrate is at most a few hundred A, thus the channel width is considerably restricted by the SOI thickness.

A MOS transistor having the GAA structure (GAA MOS transistor) is disclosed in U.S. Pat. No. 5,497,019. According to the GAA MOS transistor, an active pattern is formed on the SOI layer and a gate insulation layer is formed on a whole surface of the active pattern. A channel region is formed on the active pattern and the gate electrode surrounds the channel region, thus the narrow width effect is prevented and the channel conductivity is improved similarly to the DELTA MOS transistor.

However, the GAA MOS transistor also has problems as follows.

When the gate electrode surrounds the active pattern corresponding to the channel region, a buried oxide layer underlying the active pattern on the SOI layer needs to be etched using an under-cut etching process. However, since the SOI layer is utilized as a source/drain region as well as the channel region, the isotropic etching process removes the source/drain region as well as a lower portion of the channel region. Therefore, when a conductive layer is formed on the channel region for the gate electrode, the gate electrode is formed on the source/drain regions as well as the channel region. Thus, parasitic capacitance is increased in the GAA MOS transistor.

In addition, a lower portion of the channel region is horizontally etched away during the isotropic etching process, so that a horizontal length (or a width) of a tunnel that is to be buried by the gate electrode in a subsequent process is increased. That is, according to the GAA MOS transistor, the gate length is hardly reduced below the width of the channel.

Accordingly, there is still a need for an improved manufacturing method for a semiconductor device that overcomes the above problems due to the recent size-down trend of the semiconductor device.

### SUMMARY OF THE INVENTION

Accordingly, the present invention provides a semiconductor device for improving carrier mobility.

The present invention also provides a method of manufacturing the above semiconductor device.

According to an exemplary embodiment of the present invention, there is provided a semiconductor device comprising a fin body protruded from a substrate and extending in a first direction substantially parallel with the substrate, a channel layer formed on a top surface and first and second side surfaces of the fin body, a gate insulation layer formed on the channel layer, and a gate electrode formed on the gate insulation layer in the second direction. The first and second side surfaces of the fin body face each other in a second direction substantially perpendicular to the first direction.

According to another exemplary embodiment of the present invention, there is provided a method of fabricating a semiconductor device. A fin body is protruded from a substrate and extends in a first direction. A channel layer is formed on a surface of the fin body. A gate insulation layer is formed on the channel layer, and a conductive layer is formed on the substrate to cover the gate insulation layer. A gate electrode is formed in a second direction substantially perpendicular to the first direction by patterning the conductive layer.

According to still another exemplary embodiment of the present invention, there is provided another method of fabricating a semiconductor device. A structure is formed on a substrate to have an opening through which a surface of the substrate is exposed. A channel layer is formed on the surface of the substrate exposed by the opening. A gate insulation layer is formed on the channel layer, and a gate electrode is formed on the gate insulation layer within the opening.

According to still another exemplary embodiment of the present invention, there is provided still another method of fabricating a semiconductor device. A channel layer is formed on a surface of a substrate, and a single crystalline silicon layer is formed on the channel layer. A gate insulation layer is formed by thermally oxidizing the single crystalline silicon layer. A gate electrode is formed on the gate insulation layer, and source/drain regions are formed on the substrate facing each other with respect to the gate electrode.

A selective epitaxial growth (SEG) process may be utilized for forming the channel layer, and in particular, a channel region of a fin FET may be formed in the channel layer. The channel layer of the present invention preferably comprises a material of high carrier mobility such as silicon germanium (SiGe), germanium (Ge), silicon carbide (SiC).

In an embodiment of the present invention, an advantage is that the carrier mobility of the channel layer can be remarkably improved as compared with a conventional channel layer; thus a driving current of the semiconductor device increases to thereby improve operating characteristics.

### BRIEF DESCRIPTION OF THE DRAWINGS

The above and other features and advantages of the present invention will become readily apparent by reference to the following detailed description of various exemplary embodiments by reference to the accompanying drawings, in which:

FIG. 1 is a plan view illustrating a semiconductor device of an exemplary embodiment;

FIG. 2 is a cross sectional view taken along the line I-I′ of the semiconductor device shown in FIG. 1;

FIG. 3 is a cross sectional view taken along the line II-II′ of the semiconductor device shown in FIG. 1;

FIGS. 4 through 17 are views illustrating an exemplary embodiment of a method of fabricating a semiconductor device shown in FIGS. 1 to 3;

FIGS. 18 through 26 are views illustrating another embodiment of a method of fabricating a semiconductor device show in FIGS. 1 to 3;

FIGS. 27 through 32 are views illustrating still another embodiment of a method of fabricating a semiconductor device show in FIGS. 1 to 3; and

FIGS. 33 through 36 are views illustrating further still another embodiment of a method of fabricating a semiconductor device show in FIGS. 1 to 3.

### DESCRIPTION OF THE EMBODIMENTS

The present invention now will be described more fully hereinafter with reference to the accompanying drawings in which exemplary embodiments of the present invention are shown.

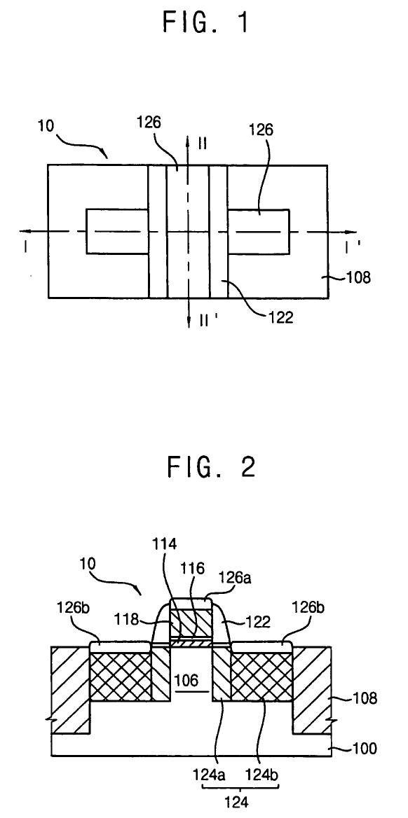

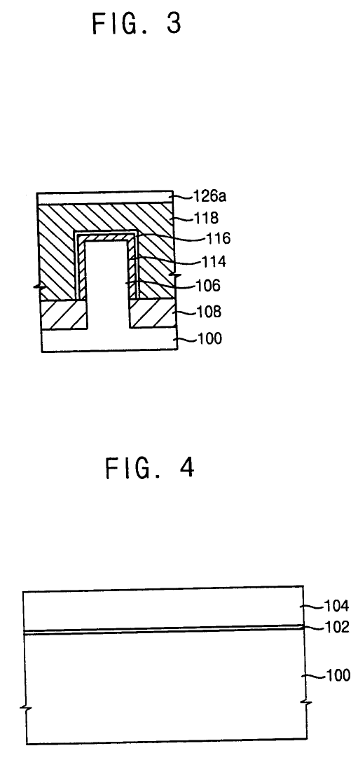

FIG. 1 is a plan view illustrating a semiconductor device according to an exemplary embodiment of the present invention. FIG. 2 is a cross sectional view taken along the line I-I′ of the semiconductor device shown in FIG. 1, and FIG. 3 is a cross sectional view taken along the line II-II′ of the semiconductor device shown in FIG. 1.

Referring to FIGS. 1 to 3, the semiconductor device 10 according to an exemplary embodiment of the invention includes a fin body 106 protruded from a substrate 100 such as a silicon wafer. The fin body 106 extends in a first direction (e.g., along or parallel to line I-I′) across the substrate 100, and is surrounded by a field insulation pattern 108. A conventional shallow trench isolation (STI) process may exemplarily be utilized for the field insulation pattern 108. The semiconductor device 10 including the fin body 106 is an example of a type of device known as a fin field effect transistor (FET) device.

A channel layer 114 on which a channel is to be formed in a subsequent process is formed on a top surface and on first and second side surfaces of the fin body 106 as best seen in FIG. 3. The first side surface faces the second side surface in a second direction substantially perpendicular to the first direction. In other words, the first and second side surfaces are on opposite sides of fin body 106 and preferable are mutually parallel. As an exemplary embodiment, the channel layer 114 comprises at least one element in group IV in the periodic table. In the present embodiment, the channel layer 114 is formed on a first surface portion of the fin body 106 in the first direction, so that the channel layer 114 has a predetermined width in the first direction (e.g., along line I-I′, as shown in FIG. 2). Source/drain regions 124 are formed on a second surface portion of the fin body 106 symmetrically with respect to the channel layer 114 in the first direction. The second surface portion of the fin body 106 corresponds to a remaining surface portion of the fin body 106 on which the channel layer 114 is not formed, and is divided into two sub-portions by the channel layer 114. The source/drain regions 124 are formed on the two sub-portions of the second surface portion of the fin body, so that the source region faces the drain region along the first direction symmetrically with respect to the channel region of the first portion of the fin body 104 as shown in FIG. 2.

A selective epitaxial growth (SEG) process may be utilized for forming the channel layer 114, and the channel layer 114 may exemplarily comprise a material having high carrier mobility. For example, the channel layer 114 includes a silicon germanium (SiGe) layer, a germanium (Ge) layer, a silicon carbide (SiC) layer or combinations thereof. The channel layer 114 can further include a single crystalline silicon layer, as would be known to those of ordinary skill in the art.

A gate insulation layer 116 is formed on the channel layer 114. The gate insulation layer 116 includes a material layer comprising a high-k material, a silicon oxide (SiO2) layer, a silicon nitride (SiN) layer, a silicon oxynitride (SiON) layer or combinations thereof. The high-k material indicates a material having a high dielectric constant, and examples of the high-k material layer include a yttrium oxide (Y2O3) layer, a hafnium oxide (HfO2) layer, a zirconium oxide (ZrO2) layer, a niobium oxide (Nb2O5) layer, a barium titanate (BaTiO3), a strontium titanate (SrTiO3), etc. These can be used alone or in combinations thereof. An atomic layer deposition (ALD) process or a metal organic chemical vapor deposition (MOCVD) process or other dielectric deposition technique may be utilized for the high-k material layer. In addition, a combination layer of the silicon oxide (SiO2) layer and the silicon nitride (SiN) layer may be utilized as the gate insulation layer 116, and another combination layer of the silicon oxide (SiO2) layer, the silicon nitride (SiN) layer and the silicon oxynitride (SiON) layer may also be utilized as the gate insulation layer 116. The single crystalline silicon layer may be further formed between the channel layer 114 and the gate insulation layer 116.

A gate electrode 118 is formed on the gate insulation layer 116 in the second direction substantially perpendicular to the first direction as shown in FIG. 3. The gate electrode 118 includes a polysilicon layer doped with impurities such as predetermined conductive type dopants. The gate electrode 118 can also further include a metal silicide layer formed on the polysilicon layer 126a, as would be known to those of ordinary skill in the art. In an example of the present embodiment, a metal layer is formed on the doped polysilicon layer, and then a heat treatment is performed on the metal layer to thereby form the metal silicide layer 126a. Examples of the metal layer include a tungsten (W) layer, titanium (Ti) layer, a cobalt (Co) layer, a nickel (Ni) layer, a ruthenium (Ru) layer, etc. These can be used alone or in combinations thereof.

An ion implantation process is performed on the fin body 106 to thereby form the source/drain regions 124, and the source/drain regions include a lightly doped area (124a) and a highly doped area (124b), respectively. In addition, a metal silicide layer 126b is formed on the source/drain regions 124 to reduce a contact resistance to the source/drain regions 124.

A spacer 122 is formed on a side surface of the gate electrode 118, and comprises an insulation material such as silicon nitride or other dielectric materials as known in the art. In the present embodiment, a pair of the spacers 122 is formed on both side surfaces of the gate electrode 118, so that each of the spacers 122 faces each other in the first direction as shown in FIG. 2.

In the present embodiment, the substrate 10 may include a bulk-silicon wafer, an epitaxial silicon wafer or a silicon-on-insulator (SOI) wafer.

According to an embodiment of the present invention, the channel layer 114 on the fin body 106 can improve carrier mobility of the semiconductor device 10 to increase driving current of the semiconductor device 10. Thus, in this embodiment, the performance of the semiconductor device 10 can be remarkably improved as compared with a conventional semiconductor device.

In the above description, the line I-I′ in FIG. 1 corresponds to the first direction, and the line II-II′ in FIG. 1 corresponds to the second direction.

FIGS. 4 through 17 are views illustrating processing steps for a method of fabricating a semiconductor device shown in FIGS. 1 to 3.

Referring to FIG. 4, a cross-sectional view similar to FIG. 2, a pad oxide layer 102 and a capping layer 104 are sequentially formed on a substrate 100 such as a silicon wafer. A thermal oxidation process or a chemical vapor deposition (CVD) process may be performed on the substrate 100 for forming the pad oxide layer 102. A low-pressure chemical vapor deposition (LPCVD) process or a plasma enhanced chemical vapor deposition (PECVD) process may be performed on the substrate 100 for forming the capping layer 104 using various gases such as dichlorosilane (SiH2Cl2) gas, silane (SiH4) gas and ammonia (NH3) gas.

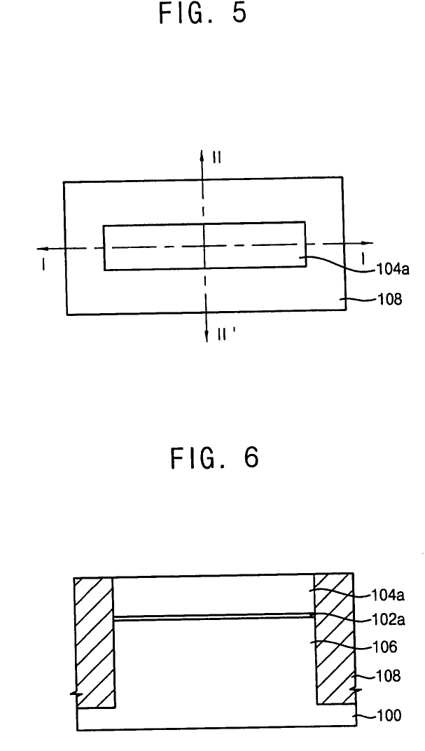

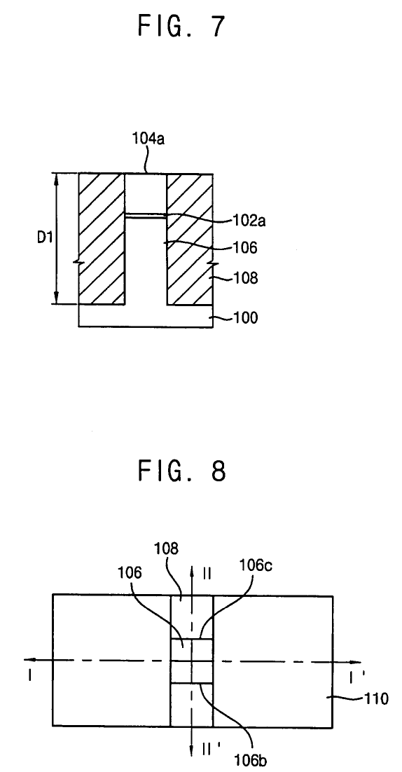

FIG. 5 is a plan view similar to FIG. 1 illustrating the fin body protruded from the substrate according to an exemplary embodiment of the present invention. FIG. 6 is a cross sectional view taken along the line I-I′ of the fin body shown in FIG. 5, and FIG. 7 is a cross sectional view taken along the line II-II′ of the fin body shown in FIG. 5.

Referring to FIGS. 5 to 7, the capping layer 104, the pad oxide layer 102 and a surface of the substrate 100 are patterned to thereby form a fin body 106, a pad oxide pattern 102a and a capping pattern 104a on the substrate 100.

In the present embodiment, a first photoresist pattern (not shown) is formed on the capping layer 104, and a first opening (not shown) is formed on the first photoresist pattern in a first direction across the substrate 100. The capping layer 104 and the pad oxide layer 102 are etched away using the first photoresist pattern as an etching mask, to thereby form the capping pattern 104a and the pad oxide pattern 102a in the first direction. A plasma etching process or a reactive ion etching process may be utilized for the capping pattern 104a and the pad oxide pattern 102a. A conventional photolithography process may be utilized for the first photoresist pattern.

The first photoresist pattern is removed through conventional ashing and strip processes, and an anisotoprical etching process is performed on the substrate 100 using the capping pattern 104a as an etching mask. Accordingly, a surface of the substrate 100 is partially removed to a predetermined depth, so that a recessed portion groove or trench is formed in the surface of the substrate 100. Accordingly, an un-etched portion of the substrate 100 protected by capping pattern 104a is relatively protruded from the recessed portion of the substrate 100 in the first direction. The un-etched portion of the substrate 100 is formed to be a fin body 106 protruded from the substrate 100 and extending in the first direction. In the present embodiment as shown in FIG. 7, a depth D1 of the recessed portion of the substrate 100 is in a range between about 2000 Å and about 3000 Å, so that the fin body 106 has a height above a bottom of the recessed portion of about 2000 Å to about 3000 Å. Examples of the anisotoprical etching process include a conventional dry etching process such as a plasma etching process, a reactive ion etching process, etc.

A field insulation layer (not shown) is formed on the capping pattern 104a to sufficient thickness to fill the recessed portion of the substrate 100, and then is partially removed and planarized until a top surface of the capping pattern 104a is exposed to thereby form a field insulation pattern 108. The field insulation pattern 108 functions as a device isolation layer on the substrate 100, so that conductive structures on the substrate are isolated with each other. An etch-back process or a chemical mechanical polishing (CMP) process may be utilized for the planarization of the field insulation layer.

In the present embodiment, the field insulation pattern 108 has a height of about 4000 Å to about 6000 Å from a bottom surface of the recessed portion, and comprises silicon oxide using a CVD process or a high-density plasma CVD process.

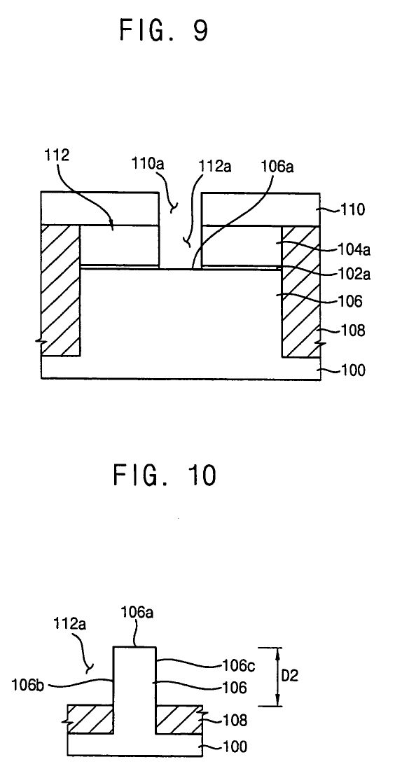

FIG. 8 is a plan view illustrating an opening through which the fin body is partially exposed. FIG. 9 is a cross sectional view taken along the line I-I′ of the opening shown in FIG. 8, and FIG. 10 is a cross sectional view taken along the line II-II′ of the opening shown in FIG. 8.

Referring to FIGS. 8 to 10, a second photoresist pattern 110 is formed on the capping pattern 104a and the field insulation layer 108, and a second opening 110a (FIG. 9) is formed on the second photoresist pattern 110 in a second direction substantially perpendicular to the first direction. An anisotropical etching process is performed on the substrate 100 including the capping pattern 104a and the pad oxide pattern 102a using the second photoresist pattern 110 as an etching mask to form a structure 112 in which the fin body 106 is partially exposed. The capping pattern 104a and the pad oxide pattern 102a are partially removed correspondently to the second opening 110a to thereby form a third opening 112a in the second direction through which the fin body 106 is partially exposed. That is, the third opening 112a in FIG. 9 is defined by the capping pattern 104a, the pad oxide pattern 102a and the field insulation layer 108. Accordingly, the structure 112 includes a pad oxide pattern 102a and the capping pattern 104a on a top surface 106a of the fin body 106 and the field insulation layer 108 that surrounds lower portions of a first side surface 106b and a second side surface 106c on opposite sides of the fin body 106. The first side surface 106b faces oppositely from the second side surface 106c in the second direction. The top surface 106a and the first and second side surfaces 106b and 106c of the fin body 106 are partially exposed through the third opening 112a. As an exemplary embodiment, the field insulation layer 108 is partially removed to a depth of about 1500 Å to about 2000 Å from the top surface 106a of fin body 106 as shown in FIG. 10. A conventional photolithography process may be utilized for the second photoresist pattern 110, and the second photoresist pattern 110 is removed through a conventional ashing and strip processes after completing the third opening 112a.

A doping process with impurities is performed on the exposed fin body 106 within the third opening 112a to thereby form a channel region (not shown) on the fin body 106. The doping process can include an ion implantation process and a diffusion process, and the impurities can include P type and N type dopants. The doping process for the channel may be formed regardless of the pad oxide layer. When the doping process is performed prior to the pad oxide layer, the impurities can be introduced and diffused into surface portions of the substrate 100 by diffusion. When the doping process is performed posterior to the pad oxide layer, the impurities are implanted into surface portions of the substrate 100 by ion implantation.

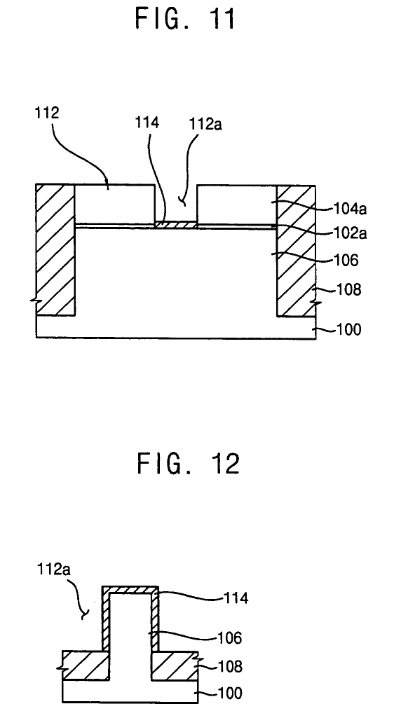

FIG. 11 is a cross sectional view taken along the first direction of the channel layer on a portion of the fin body similar to FIG. 9 but after removal of pattern 110, FIG. 12 is a cross sectional view similar to FIG. 10 taken along the second direction of the channel layer on a portion of the fin body within opening 112a.

Referring to FIGS. 11 and 12, the channel layer 114 is formed on a portion of the fin body 106 exposed through the third opening 112a. A SEG process may be utilized for the channel layer 114, and the channel layer 114 comprises a material of group IV in the periodic table so as to improve carrier mobility. In the present embodiment, the channel layer 114 includes a silicon germanium (SiGe) layer, a germanium (Ge) layer, a silicon carbide (SiC) layer or combinations thereof.

When the silicon germanium layer or the germanium layer is utilized as the channel layer 114, a ultra high vacuum CVD (UVCVD), an LPCVD process or a gas source molecular beam epitaxy (GS-MBE) process may be utilized for deposition of the channel layer 114 using a silicon source gas, a germanium source gas and a carrier gas. Examples of the silicon source gas include a silane (SiH4) gas, a disilane (Si2H6) gas, a trisilane (Si3H8) gas, a monochlorosilane (SiH3Cl) gas, a dichlorosilane (SiH2Cl2) gas, a trichlorosilane (SiHCl3) gas, etc. These can be used alone or in combinations thereof. Examples of the germanium source gas include a GeH4 gas, a Ge2H6 gas, a Ge3H8 gas, a GeH3Cl gas, a GeH2Cl2 gas, a GeHCl3 gas or a compound gas thereof. Examples of the carrier gas include a chlorine (Cl2) gas, a hydrogen (H2) gas, a hydrogen chloride (HCl) gas or combinations thereof.

When the silicon carbide layer is utilized as the channel layer 114, a CVD process or an atomic layer epitaxy (ALE) process may be utilized for depositing the channel layer 114 using a silicon source gas, a carbon source gas and a carrier gas. Examples of the silicon source gas include a silane (SiH4) gas, a disilane (Si2H6) gas, a trisilane (Si3H8) gas, a monochlorosilane (SiH3Cl) gas, a dichlorosilane (SiH2Cl2) gas, a trichlorosilane (SiHCl3) gas, etc. These can be used alone or in combinations thereof. Examples of the carbon source gas include an ethane (C2H2) gas, a carbontetrachloride (CCl4) gas, a trifluoromethane (CFH3) gas, a fluorocarbon (CF4) gas or combinations thereof. Examples of the carrier gas include a chlorine (Cl2) gas, a hydrogen (H2) gas, a hydrogen chloride (HCl) gas or combinations thereof. In addition, a Si(CH3)4 gas, a SiH2(CH3)2 gas, a SiH(CH3)3 gas, a Si2(CH3)6 gas, a (CH3)3SiCl gas, a (CH3)2SiCl2 gas or combinations thereof are exemplarily utilized as the source gas for the channel layer of the silicon carbide.

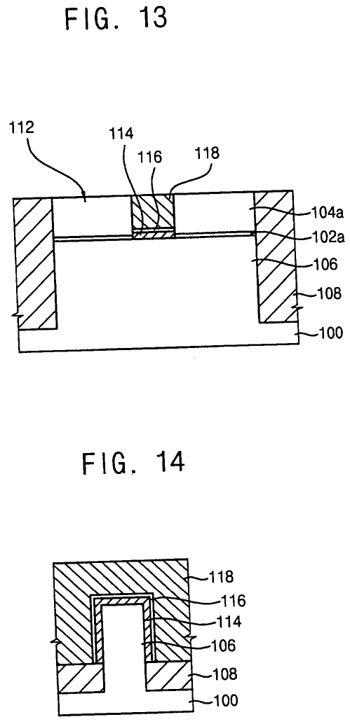

FIG. 13 is a cross sectional view similar to FIG. 11 taken along the first direction of a gate insulation layer and a gate electrode, and FIG. 14 is a cross sectional view similar to FIG. 12 taken along the second direction of the gate insulation layer and the gate electrode, showing further steps of the fabrication process.

Referring to FIGS. 13 and 14, a gate insulation layer 116 is formed on the channel layer 114, and exemplarily includes a material layer comprising a high-k material, a silicon oxide layer, a silicon nitride layer, a silicon oxynitride layer or combinations thereof. An LPCVD process may be exemplarily utilized for the silicon oxide layer, the silicon nitride layer and the silicon oxynitride layer, and an MOCVD or an ALD process may be exemplarily utilized for the high-k material layer. Examples of the high-k material include yttrium oxide (Y2O3), hafnium oxide (HfO2), zirconium oxide (ZrO2), niobium oxide (Nb2O5), barium titanate (BaTiO3), strontium titanate (SrTiO3), etc. These can be used alone or in combinations thereof.

The silicon oxide layer may be alternatively formed through consecutive processes of a SEG and a thermal oxidation. A single crystalline silicon layer (not shown) is formed on the channel layer 114 by the SEG process, and then is thermally oxidized by the thermal oxidation process to thereby form the silicon oxide layer as the gate insulation layer 116.

When the thermal oxidation process is performed on the single crystalline silicon layer, the single crystalline silicon layer may be partially transformed into the gate insulation layer neighboring a surface thereof. Thus a portion of the single crystalline silicon layer may remain between the gate insulation layer 116 and the channel layer 114. Accordingly, the structure includes the channel layer 114, the single crystalline silicon layer (not shown) and the gate insulation layer 116, which are stacked on the fin body 106.

A conductive layer (not shown) is formed on the capping pattern 104a to a sufficient thickness such that the third opening 112a is filled with the conductive layer, and then the conductive layer is removed and planarized until a top surface of the capping pattern 140a is exposed. An etch-back process or a CMP process may be utilized for planarizing the conductive layer. Accordingly, a portion of the conductive layer only remains in the third opening 112a to thereby form a gate electrode 118. The conductive layer may comprise polysilicon doped with impurities. Polysilicon can be deposited on the capping pattern 104a using an LPCVD process and the impurities are implanted through in-situ processing to thereby form the doped polysilicon layer.

Alternatively, the gate electrode 118 may include the doped polysilicon layer and a metal silicide layer on the doped polysilicon layer though the silicide is not shown in figures. In a particular example, after the doped polysilicon layer is formed on the capping pattern 104a, the field insulation pattern 108 and inner surfaces of the third opening 112a on which the gate insulation layer is coated, and a metal layer is formed with the third opening 112a. Then, a heat treatment is performed on the metal layer to thereby form the metal silicide layer.

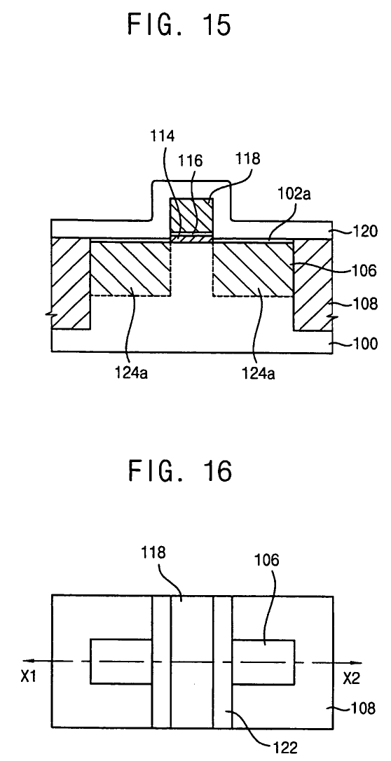

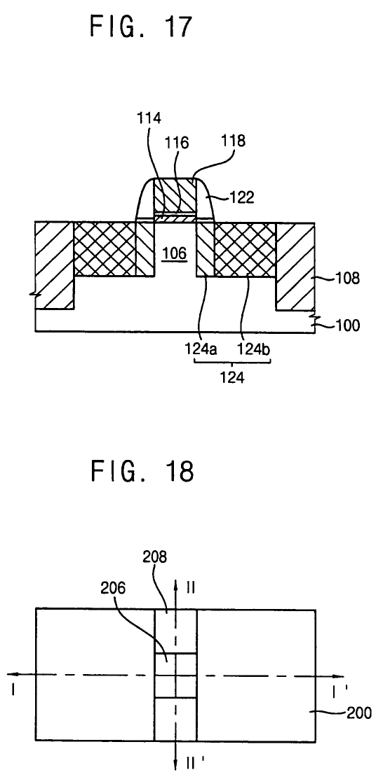

FIG. 15 is a cross sectional view similar to FIG. 13 illustrating a mask layer on the gate electrode, and FIG. 16 is a plan view illustrating a spacer formed on a side surface of the gate electrode. FIG. 17 is cross sectional view taken along the line I-I′ in FIG. 16.

Referring to FIGS. 15 to 17, the capping pattern 104a and an upper portion of the field insulation pattern 108 are removed by using an isotropical or an anisotropical etching process to expose the pad oxide pattern 102a and the gate electrode 118. A mask layer 120 is formed over the exposed pad oxide pattern 102a and the gate electrode 118, and exemplarily comprises silicon nitride or silicon oxide. A CVD process, an LPCVD process or a PECVD process may be utilized for depositing the mask layer 120.

The mask layer 120 is anisotropically etched, so that spacers 122 are formed on both side surfaces of the gate electrode 118. In the present embodiment, the side surfaces face oppositely from each other in the first direction.

Source/drain regions 124 are formed on the fin body 106 symmetrically with respect to the gate electrode 118 in the first direction. Each of the source/drain regions 124 includes a lightly doped area 124a and a highly doped area 124b. In the present embodiment, the lightly doped area 124a is formed by ion implantation before the mask layer 120 is formed (FIG. 15), and the highly doped area 124b is formed by ion implantation using the spacers 122 as a mask after the spacers are formed (FIG. 17). A conventional etching process may be utilized for removing the pad oxide pattern 102a in the source/drain regions 124.

A metal layer (not shown) is formed on the source/drain regions 124, the spacers 122 and the gate electrode 118, and a heat treatment is consecutively performed on the metal layer to thereby form the metal silicide layers 126a and 126b shown in FIG. 1 on the gate electrode 118 and the source/drain regions 124. Examples of the metal layer include a tungsten layer, a titanium layer, a tantalum layer, a cobalt layer, a nickel layer and a ruthenium layer. These or other suitable metals can be used alone or in a combination thereof.

Then, the portion of the metal layer that is not transformed into the metal silicide layer during the heat treatment and remains on the source/drain regions 124, the spacers 122 and the gate electrode 118 is completely removed by etching to complete the semiconductor device 10 as shown in FIGS. 1 to 3.

FIGS. 18 through 26 are views illustrating processing steps for another method of fabricating a semiconductor device show in FIGS. 1 to 3.

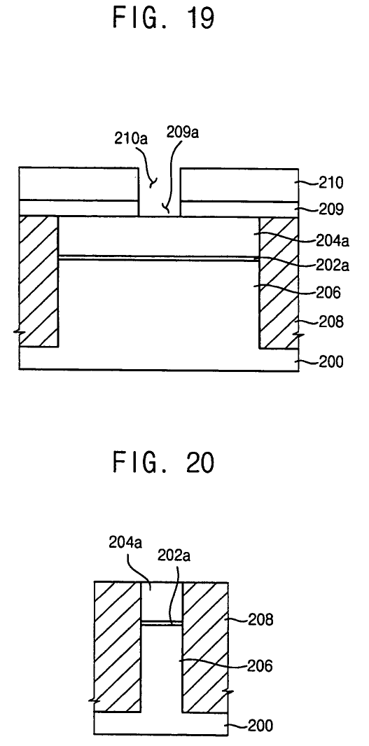

FIG. 18 is a plan view similar to FIG. 8 illustrating a mask pattern for forming an opening through which a side surface of a fin body is partially exposed. FIG. 19 is a cross sectional view taken along the line I-I′ of the mask pattern shown in FIG. 18, and FIG. 20 is a cross sectional view taken along the line II-II′ of the mask pattern shown in FIG. 18.

Referring to FIGS. 18 to 20, a fin body 206 is formed on a substrate 200 such as a silicon wafer in a first direction, and a pad oxide pattern 202a and a capping pattern 204a are formed on the fin body 206. A field insulation pattern 208 is also formed to enclose the fin body 206, the pad oxide pattern 202a and the capping pattern 204a. The procedures for forming fin body 206, the pad oxide pattern 202a, the capping pattern 204a and the field insulation pattern 208 are similar to those described with reference to FIGS. 4 to 7; thus a detailed description is omitted below to avoid redundancy.

A first mask layer (not shown) is formed on the field insulation layer 208 and the capping pattern 204a, and a first photoresist pattern 210 is formed on the mask layer. A first opening 210a is formed on the first photoresist pattern 210 in a second direction substantially perpendicular to the first direction. The first mask layer exemplarily comprises silicon nitride or silicon oxide, and a CVD process, an LPCVD process or a PECVD process may be utilized for the first mask layer. A conventional photolithography process may be utilized for the first photoresist pattern 210.

An anisotropical etching process is performed on the first mask layer using the first photoresist pattern 210 as an etching mask to form a mask pattern 209 having a second opening 209a through which the capping pattern 204a and the field insulation pattern 208 are partially exposed. The first photoresist pattern 210 is then removed through conventional ashing and strip processes after completing the mask pattern 209.

Hereinafter, the first direction indicates a direction of the line I-I′ shown in FIG. 18, and the second direction indicates a direction of the line II-II′ shown in FIG. 18.

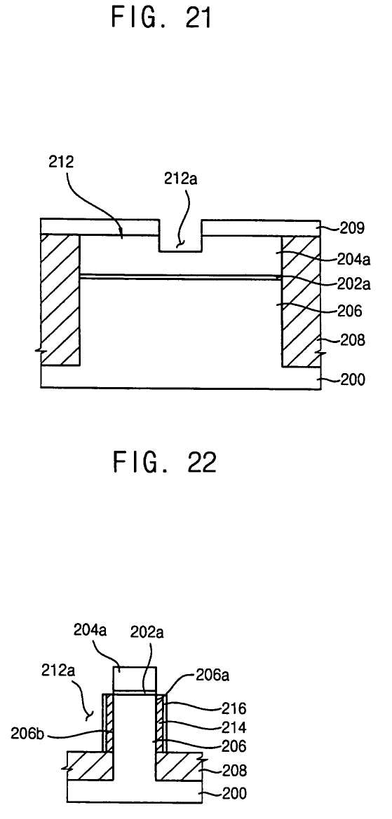

FIG. 21 is a cross sectional view taken along the first direction of the channel layer formed on a side surface of the fin body, and FIG. 22 is a cross sectional view taken along the second direction of the channel layer formed on a side surface of the fin body.

Referring to FIGS. 21 and 22, an anisotropical etching process is performed using the mask pattern 209 as an etching mask to form a structure 212 including a third opening 212a through which a side surface of the fin body 206 is exposed. The capping pattern 204a is also partially etched away during the etching process for the structure 212.

A channel layer 214 is formed on first and second side surfaces 206a and 206b of the fin body 206 exposed through the third opening 212a. The first side surface 206a is opposite the second side surface 206b in the second direction. A SEG process may be performed on the first and second side surfaces 206a and 206b of the fin body 206 for the channel layer 214. In the present embodiment, the channel layer 214 includes a silicon germanium (SiGe) layer, a germanium (Ge) layer, a silicon carbide (SiC) layer or combinations thereof. The channel layer 214 is similar to the layer 114 described with reference to FIGS. 11 to 12; thus a more detailed description of the channel layer 214 can be omitted below to avoid a redundancy.

An additional etching process may be performed on the fin body 206 prior to forming the channel layer 214 for scaling down a width of the fin body 206. That is, the first and second side surfaces 206a and 206b of the fin body 206 are additionally etched away to scale down the width of the fin body 206.

Then, a gate insulation layer 216 is formed on the channel layer 214, and may exemplarily comprise high-k material, silicon oxide, silicon nitride, silicon oxynitride or combinations thereof. When the silicon oxide is utilized for the gate insulation layer 216, consecutive processes of a SEG and a thermal oxidation are performed for the silicon oxide layer. A single crystalline silicon layer (not shown) is formed on the channel layer 214 by the SEG process, and then is thermally oxidized by the thermal oxidation process to thereby transform the silicon oxide layer into the gate insulation layer 216.

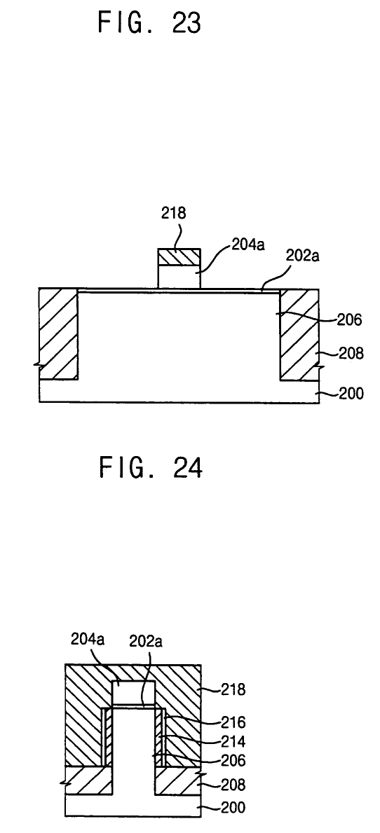

FIG. 23 is a cross sectional view taken along the first direction of a gate electrode on the gate insulation layer, and FIG. 24 is a cross sectional view taken along the second direction of a gate electrode on the gate insulation layer.

Referring to FIGS. 23 and 24, a conductive layer (not shown) is formed to a sufficient thickness such that the third opening 212a is filled with the conductive layer, and then the conductive layer is removed and planarized until a top surface of the capping pattern 204a or the mask pattern 209 is exposed. An etch-back process or a CMP process may be utilized for planarizing the conductive layer. Accordingly, the conductive layer only remains in the third opening 212a to thereby form a gate electrode 218 in the second direction. Alternatively, the conductive layer is removed and planarized until a top surface of the fin body 206 is exposed, so that a pair of gate electrodes that are separated from each other is formed.

The conductive layer that forms electrode 218 may comprise polysilicon doped with impurities. The polysilicon layer is formed on the capping pattern 204a using an LPCVD process and the impurities are implanted in-situ in the deposition process to thereby form the doped polysilicon layer. Alternatively, the gate electrode 118 may include the doped polysilicon layer and a metal silicide layer formed on the doped polysilicon layer though not shown in figures. The gate electrode 218 is also similar to that described with reference to FIGS. 13 and 14, thus a detailed description of the gate electrode 218 is omitted below to avoid a redundancy.

Then, the capping pattern 204a and an upper portion of the field insulation pattern 208 are removed using a conventional etching process to expose the pad oxide pattern 202a and the gate electrode 218.

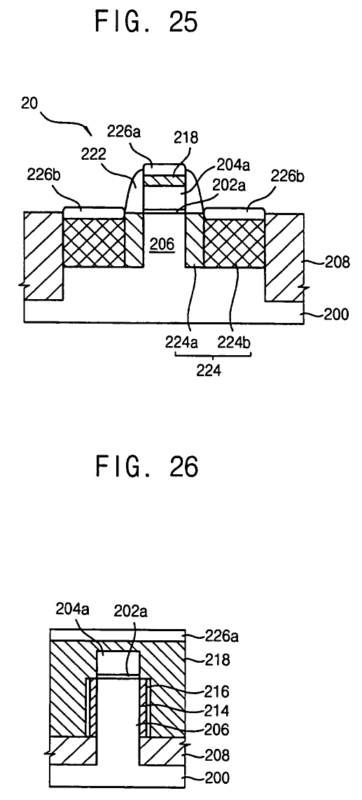

FIG. 25 is a cross sectional view taken along the first direction, transversely of spacers on opposite side surfaces of the gate electrode. FIG. 26 is cross sectional view taken along the second direction similar to FIG. 24 but after forming spacers on sides surface of the gate electrode.

Referring to FIGS. 25 and 26, a second mask layer (not shown) is formed over the capping pattern 204a and the gate electrode 218, and anisotropically etched away. Thus a spacer 222 is respectively formed on both side surfaces of the gate electrode 218.

Source/drain regions 224 are formed on the fin body 206 symmetrically with respect to the gate electrode 218 in the first direction. Each of the source/drain regions 224 includes a lightly doped area 224a and a highly doped area 224b. In the present embodiment, the lightly doped area 224a is formed by ion implantation before the spacer 222 is formed, and the highly doped area 224b is formed by ion implantation using the spacer 222 as a mask after the spacer 222 is formed. A conventional etching process may be utilized for removing the pad oxide pattern 202a in the source/drain regions 124.

A metal layer (not shown) is formed on the source/drain regions 224, the spacers 222, the gate electrode 218 and the field insulation pattern 208, and a heat treatment is consecutively performed on the metal layer to thereby form metal silicide layers 226a and 226b on the gate electrode 218 and the source/drain regions 224. Then, any portion of the metal layer that is not transformed into the metal silicide layer during the heat treatment and remains on the source/drain regions 224, the spacers 222 and the gate electrode 218, is completely removed to complete the semiconductor device 20.

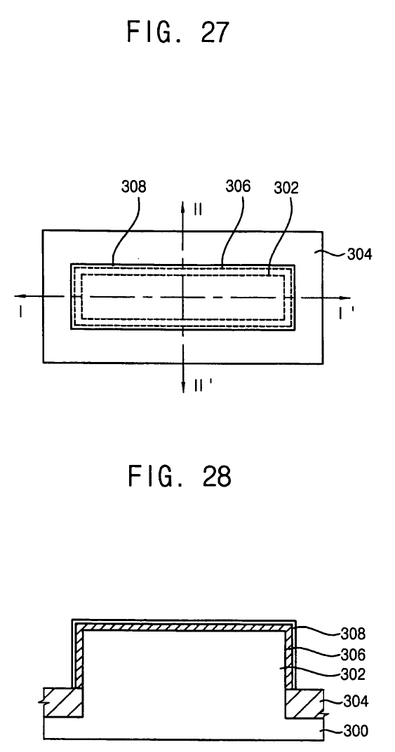

FIGS. 27 through 32 are views illustrating processing steps for still another method of fabricating a semiconductor device show in FIGS. 1 to 3.

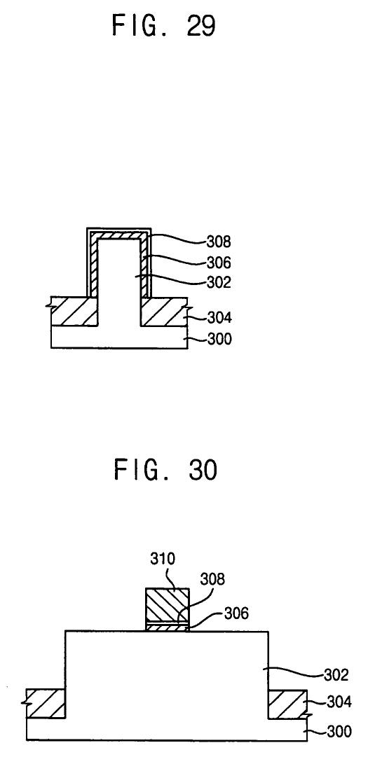

FIG. 27 is a plan view illustrating a fin body formed on a substrate. FIG. 28 is a cross sectional view taken along the line I-I′ of the fin body shown in FIG. 27, and FIG. 29 is a cross sectional view taken along the line II-II′ of the fin body shown in FIG. 27.

Referring to FIGS. 27 to 29, a pad oxide layer (not shown) is formed on a substrate 300 such as a silicon wafer, and a first mask layer (not shown) is formed on the pad oxide layer. A first photoresist pattern (not shown) is formed on the first mask layer in a first direction across the substrate 300, and the first mask layer is anisotropically etched away using the first photoresist pattern as an etching mask to thereby form a first mask pattern (not shown) on the substrate 300 in the first direction.

The first mask layer exemplarily comprises silicon nitride or silicon oxide, and a CVD, an LPCVD or a PECVD may be utilized for the first mask layer. A conventional photolithography process may be utilized for the first photoresist pattern.

The first photoresist pattern is removed by conventional ashing and stripping processes, and the pad oxide layer and the substrate 300 are anisotropically etched away using the first mask pattern. Accordingly, a surface of the substrate 300 is partially removed to a predetermined depth, so that a recessed portion is formed on a surface of the substrate 300. An un-etched portion of the substrate 300 is relatively protruded from the recessed portion of the substrate 300 in the first direction. The un-etched portion of the substrate 300 is formed to be a fin body 302 that is protruded from the substrate 300 and extending in the first direction. The fin body 302 includes first and second side surfaces facing oppositely from each other in a second direction substantially perpendicular to the first direction.

A field insulation layer (not shown) is formed on the substrate 300 to a sufficient thickness to fill the recessed portion of the substrate 300, and then is partially removed and planarized until a top surface of the fin body 302 is exposed to thereby form a field insulation pattern 304. An etch-back process or a chemical mechanical polishing (CMP) process may be utilized for the field insulation pattern 304. The field insulation pattern 304 is consecutively etched away to a predetermined depth to expose the first and second side surfaces of the fin body 302. That is, the top and side surfaces of the fin body 302 are exposed after the field insulation pattern 304 is completed.

A channel layer 306 is formed on the fin body 302, and a gate insulation layer 308 is formed on the channel layer 306. The channel layer 306 exemplarily includes a silicon germanium (SiGe) layer, a germanium (Ge) layer, a silicon carbide (SiC) layer or combinations thereof, and the gate insulation layer exemplarily includes a high-k material layer, a silicon oxide layer, a silicon nitride layer, a silicon oxynitride layer or combinations thereof.

When a CVD process or an ALD process is utilized for the gate insulation layer 308, the gate insulation layer is formed on the channel layer 306 and the field insulation pattern 304. In contrast, when a thermal oxidation process is utilized for forming the silicon oxide layer as the gate insulation layer 308, the gate insulation layer 308 is formed only on the channel layer 306. In detail, a single crystalline silicon layer is formed on the channel layer 306, and then the single crystalline silicon layer is thermally oxidized to thereby form the silicon oxide layer. The channel layer 306 and the gate insulation layer 308 are similar to those described with reference to FIGS. 11 to 14, thus a detailed description on the channel layer and the gate insulation layer is omitted below.

Although the above embodiment of the invention discusses the channel layer 306 and the gate insulation layer 308 on the top and side surfaces of the fin body, the channel layer 306 and the gate insulation layer 308 could be formed only on the side surfaces of the fin body, as would be known to one of the ordinary skill in the art. The field insulation layer is removed until a top surface of the first mask pattern is exposed using a CMP or an etch-back process, and the field insulation pattern 304 is additionally etched away to a predetermined depth to expose opposite side surfaces of the fin body 302. Then, the channel layer 306 and the gate insulation layer 308 are formed only on the side surfaces of the fin body 302.

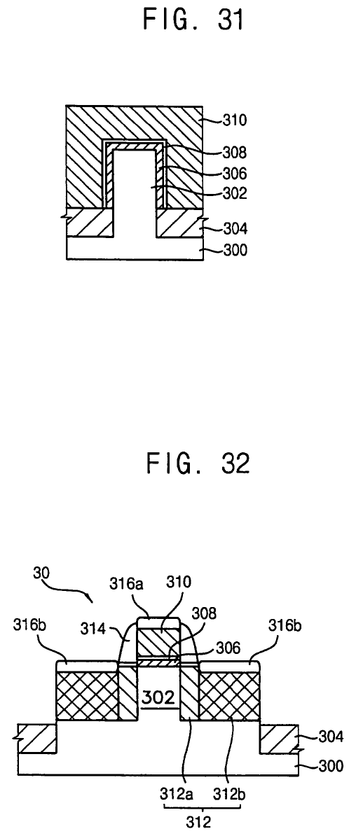

FIG. 30 is a cross sectional view taken along the first direction of a gate electrode on the gate insulation layer. FIG. 31 is cross sectional view taken along the second direction of a gate electrode on the gate insulation layer.

Referring to FIGS. 30 and 31, a conductive layer (not shown) is formed on the gate insulation layer 308 and the field insulation pattern 304 to a sufficient thickness to cover the gate insulation layer 308. The conductive layer may comprise doped polysilicon, and an LPCVD process may be utilized for depositing the polysilicon doped with impurities in-situ.

Then, the conductive layer is planarized using a CMP process or an etch-back process. Optionally, a metal silicide layer is further formed on the conductive layer after the planarization process. A second mask layer (not shown) is next formed on the conductive layer. A second photoresist pattern (not shown) extending in the second direction is formed on the second mask layer. The second mask layer is anisotropically etched away using the second photoresist pattern as an etching mask to thereby form a second mask pattern (not shown).

The second mask layer exemplarily comprises silicon nitride or silicon oxide, and a CVD, an LPCVD or a PECVD may be utilized for deposition of the second mask layer. A conventional photolithography process may be utilized for the second photoresist pattern.

The second photoresist pattern is removed by conventional ashing and stripping processes, and the conductive layer is anisotropically etched away using the second mask pattern to form a gate electrode extending in the second direction.

All of the channel layer 306 and the gate insulation layer 308 are removed except for those between the gate electrode 310 and the fin body 302 during the etching process for the gate electrode 310 or through an additional subsequent etching process.

FIG. 32 is cross sectional view taken along the second direction of a spacer on a side surface of the gate electrode.

Referring to FIG. 32, a buffer oxide layer is formed on a surface of the fin body 302 using a thermal oxidation process. Impurities are lightly implanted on surface portions of the fin body 302 adjacent to both side portions of the gate electrode 310, so that both lightly doped areas 312a are formed on the fin body symmetrically with respect to the gate electrode 310 in the first direction.

A third mask layer (not shown) is formed on the buffer oxide layer and the gate electrode 310, and is anisotropically etched away to form a pair of spacers 314 on opposite side surfaces of the gate electrode 310 in the first direction. The third mask layer exemplarily comprises silicon nitride or silicon oxide, and a CVD, an LPCVD or a PECVD may be utilized for the third mask layer.

Impurities are heavily implanted on surface portions of the fin body 302 using the spacers 314 and the gate electrode 310 as an implantation mask, so that both heavily doped areas 312b are formed on the fin body 302 adjacent to the lightly doped areas 312a symmetrically with respect to the gate electrode 310 in the first direction. The lightly doped areas 312a and the heavily doped areas 312b function as source/drain regions 312 of the semiconductor device. The buffer oxide layer is removed through a conventional etching process after the source/drain regions are formed.

A metal layer (not shown) is formed on the source/drain regions 312, the spacers 314 and the gate electrode 310, and a heat treatment is performed to thereby form metal silicide layers 316a and 316b on the gate electrode 310 and the source/drain regions 312. Then, any portion of the metal layer, which is not transformed into the metal silicide layer during the heat treatment and remains on the source/drain regions 312, the spacers 314 and the gate electrode 310, is completely removed by etching to complete the semiconductor device 30.

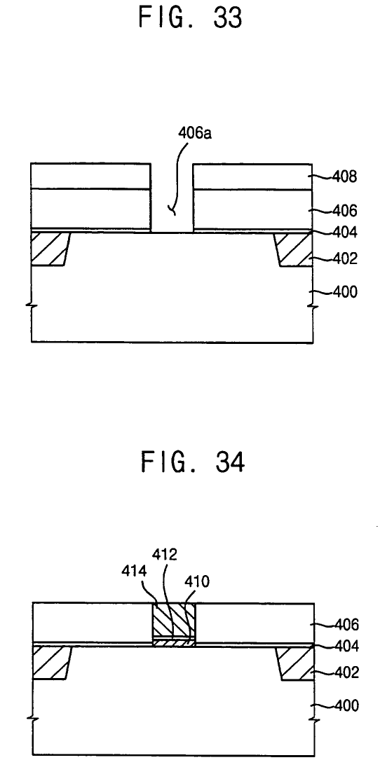

FIGS. 33 through 36 are views illustrating processing steps for further still another method of fabricating a semiconductor device show in FIGS. 1 to 3.

Referring to FIG. 33, a device isolation process such as a shallow trench isolation (STI) process and a local oxidation of silicon (LOCOS) process are performed on a substrate 400 such as a silicon wafer. Thus, a field insulation pattern 402 is formed on the substrate 400 and the substrate 400 is divided into an active region and a field region.

A pad oxide layer 404 is formed on the substrate 400 using a thermal oxidation process or a CVD process. A first mask layer (not shown) is formed on the pad oxide layer 404. The first mask layer exemplarily comprises silicon nitride or silicon oxide, and a CVD, an LPCVD or a PECVD may be utilized for depositing the third mask layer.

A first photoresist pattern 408 is formed on the first mask layer, and the first mask layer is anisotropically etched away using the first photoresist pattern 408 as an etching mask to thereby form a first mask pattern 406 on the substrate 400. The first mask pattern 406 includes an opening 406a through which a top surface of the substrate 400 is exposed. A conventional photolithography process may be utilized for the first photoresist pattern 408, and may be removed by conventional ashing and stripping processes.

FIG. 34 is a cross sectional view illustrating a channel layer, a gate insulation layer and a gate electrode formed on the substrate.

Referring to FIG. 34, a channel layer 410 is formed on the top surface of the substrate 400 in the opening 406a, and a gate insulation layer 412 is formed on the channel layer 410. The channel layer 410 exemplarily includes a silicon germanium (SiGe) layer, a germanium (Ge) layer, a silicon carbide (SiC) layer or combinations thereof, and the gate insulation layer 412 exemplarily includes a high-k material layer, a silicon oxide layer, a silicon nitride layer, a silicon oxynitride layer or combinations thereof.

A SEG process may be utilized for depositing the channel layer 410, and an LPCVD process, a MOCVD process, an ALD process or a thermal oxidation process may be utilized for depositing the gate insulation layer. The channel layer and the gate insulation layer are similar to those described with reference to FIGS. 11 to 14, so further detailed description of the channel layer and the gate insulation layer is omitted below.

A conductive layer (not shown) is formed on the gate insulation layer 412 and the first mask pattern 406 to a sufficient thickness to fill the opening 406a. The conductive layer may comprise doped polysilicon, and an LPCVD process may be utilized for depositing the polysilicon doped with impurities in-situ. Then, the conductive layer is removed and planarized using a CMP process or an etch-back process until a top surface of the first mask pattern is exposed, so that the conductive layer only remains in the opening 406a to thereby form a gate electrode 414.

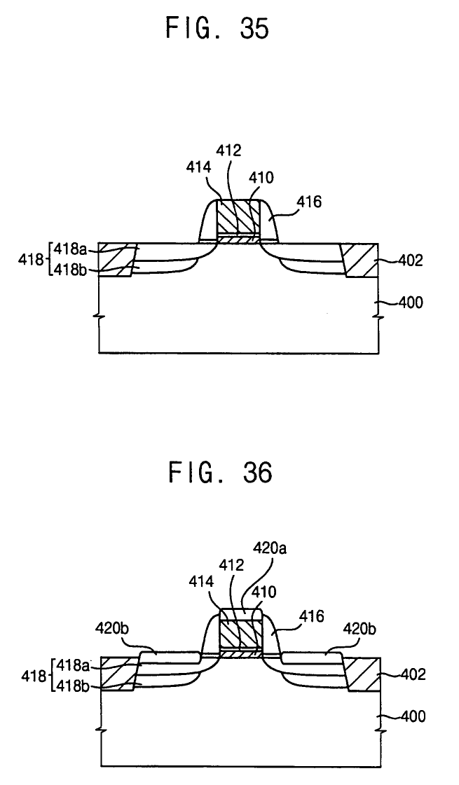

FIG. 35 is cross sectional view illustrating a spacer on side surfaces of the gate electrode.

Referring to FIG. 35, the first mask pattern 406 is removed using a conventional etching process to expose the pad oxide layer 404 and the gate electrode 414. A second mask layer (not shown) is formed on the exposed pad oxide layer 404 and the gate electrode 414. The second mask layer exemplarily comprises silicon nitride or silicon oxide, and a CVD, an LPCVD or a PECVD may be utilized for depositing the third mask layer.

Then, the second mask layer is anisotropically etched so that spacers 416 are formed on opposite side surfaces of the gate electrode 414.

Prior to formation of the second mask layer, impurities are lightly implanted in surface portions of the substrate 400 adjacent both side portions of the gate electrode 414, so that both lightly doped areas 418a are formed on the substrate 400 symmetrically with respect to the gate electrode 414. The lightly doped areas 418a extend toward a bottom portion of the substrate 400

After completing the spacers 416, impurities are heavily implanted on surface portions of the substrate 400 using the spacers 416 and the gate electrode 414 as an implantation mask to thereby form heavily doped areas 418b more deeply to the substrate 400 than the lightly doped areas 418a. The lightly doped areas 418a and the heavily doped areas 418b function as source/drain regions 418 of the semiconductor device 40. The pad oxide layer is removed through a conventional etching process after the source/drain regions 418 are formed.

FIG. 36 is a cross sectional view illustrating a metal silicide layer on the substrate.

Referring to FIG. 36, a metal layer (not shown) is formed on the source/drain regions 418, the spacers 416 and the gate electrode 414, followed by a heat treatment to thereby form metal silicide layers 420a and 420b on the gate electrode 414 and the source/drain regions 418. Then, any portion of the metal layer that is not transformed into metal silicide during the heat treatment and remains on the source/drain regions 418, the spacers 416 and the gate electrode 414, is completely removed to complete the semiconductor device 40.

According to the present invention, the channel layer of the semiconductor device comprises a material of high carrier mobility such as silicon germanium (SiGe), germanium (Ge) and silicon carbide (SiC). Thus, a driving current of the semiconductor device increases to thereby improve operation characteristics.

Although the exemplary embodiments of the present invention have been described, it is understood that the present invention should not be limited to these exemplary embodiments but various changes and modifications can be made by one skilled in the art within the spirit and scope of the present invention as hereinafter claimed.

1. A semiconductor device comprising:
a fin body protruded from a substrate and extending in a first direction substantially parallel with the substrate;
a channel layer formed on a top surface and first and second side surfaces of the fin body, the first and second side surfaces of the fin body opposite each other in a second direction substantially perpendicular to the first direction;
a gate insulation layer formed on the channel layer; and
a gate electrode formed on the gate insulation layer in the second direction.

2. The semiconductor device of claim 1, wherein the channel layer comprises an element in Group IV of a periodic table.

3. The semiconductor device of claim 1, wherein the channel layer includes a silicon germanium (SiGe) layer, a germanium (Ge) layer, a silicon carbide (SiC) layer or a combination thereof.

4. The semiconductor device of claim 1, wherein the gate insulation layer includes a material layer comprising a high-k material having a high dielectric constant, a silicon oxide layer, a silicon nitride layer, a silicon oxynitride layer or a combination thereof.

5. The semiconductor device of claim 1, further comprising a spacer formed on a side surface of the gate electrode in the first direction.

6. The semiconductor device of claim 1, wherein the gate electrode includes a polysilicon layer doped with impurities and a metal silicide layer on the polysilicon layer.

7. The semiconductor device of claim 1, wherein the channel layer is formed on a first surface portion of the fin body.

8. The semiconductor device of claim 7, wherein source and drain regions are formed on a second surface portion of the fin body different from the first portion, respectively, the source region facing the second region along the first direction symmetrically with respect to the first portion of the fin body.

9. The semiconductor device of claim 1, wherein the substrate includes a bulk-silicon wafer or a silicon-on-insulator (SOI) substrate.

10. The semiconductor device of claim 1, further comprising a single crystalline silicon layer between the channel layer and the gate insulation layer.

11. A method of fabricating a semiconductor device, comprising:
forming a fin body protruded from a substrate and extending in a first direction;
forming a channel layer on a surface of the fin body;
forming a gate insulation layer on the channel layer;
forming a conductive layer on the substrate to cover the gate insulation layer; and
forming a gate electrode in a second direction substantially perpendicular to the first direction by patterning the conductive layer.

12. The method of claim 11, wherein the channel layer comprises an element in Group IV of a periodic table.

13. The method of claim 11, wherein forming the channel layer comprises forming a silicon germanium (SiGe) layer, a germanium (Ge) layer, a silicon carbide (SiC) layer or a combination thereof.

14. The method of claim 11, further comprising forming source/drain regions on the fin body, the source region facing the drain region in the first direction with respect to the gate electrode.

15. The method of claim 11, wherein forming the channel layer includes a selective epitaxial growth (SEG) process performed on the surface of the fin body.

16. A method of manufacturing a semiconductor device, comprising:
forming a structure on a substrate to have an opening through which a surface of the substrate is exposed;
forming a channel layer on the surface of the substrate exposed by the opening;
forming a gate insulation layer on the channel layer; and
forming a gate electrode on the gate insulation layer within the opening.

17. The method of claim 16, wherein the channel layer comprises an element in Group IV of a periodic table.

18. The method of claim 16, wherein forming the channel layer comprises forming a silicon germanium (SiGe) layer, a germanium (Ge) layer, a silicon carbide (SiC) layer or combinations thereof.

19. The method of claim 16, wherein the substrate includes a bulk-silicon wafer or a silicon-on-insulator (SOI) substrate.

20. The method of claim 16, wherein forming the channel layer includes a selective epitaxial growth (SEG) process performed on the surface of the fin body.

21. The method of claim 16, further comprising forming a single crystalline silicon layer on the channel layer.

22. The method of claim 21, wherein forming the gate insulation layer includes a thermal oxidation process performed on the single crystalline silicon layer.

23. The method of claim 16, wherein forming the gate insulation layer includes a thermal oxidation process performed on a surface portion of the single crystalline silicon layer.

24. The method of claim 16, further comprising:
forming a capping layer on the substrate;
forming a fin body and a capping pattern on the fin body by etching the capping layer and the substrate, the fin body protruded from the substrate and extending in a direction substantially perpendicular to the gate electrode;
forming an insulation layer on the substrate to cover the fin body and the capping pattern; and
partially removing the insulation layer until a top surface of the capping pattern is exposed.

25. The method of claim 24, wherein forming the structure includes:
forming a photoresist pattern on the capping pattern and the insulation layer corresponding to the opening; and
forming the opening by partially etching the insulation layer using the photoresist pattern as an etching mask, so that a side surface of the fin body is exposed through the opening.

26. The method of claim 25, further comprising etching a side portion of the fin body to reduce a width of the fin body.

27. The method of claim 24, wherein forming the structure includes:
forming a photoresist pattern on the capping pattern and the insulation layer corresponding to the opening; and
forming the opening by partially etching the capping pattern and the insulation layer using the photoresist pattern as an etching mask, so that top and side surfaces of the fin body are exposed through the opening.

28. The method of claim 24, further comprising:
forming a mask pattern on the capping pattern and the insulation layer corresponding to the opening; and
forming the opening by partially etching the insulation layer using the mask pattern as an etching mask, so that a side surface of the fin body is exposed through the opening.

29. The method of claim 16, wherein forming the structure includes:
forming a mask layer on the substrate; and
forming the opening by patterning the mask layer.

30. The method of claim 16, wherein the gate insulation layer includes a material layer comprising a high-k material having a high dielectric constant, a silicon oxide layer, a silicon nitride layer, a silicon oxynitride layer or a combination thereof.

31. The method of claim 16, wherein forming the gate electrode includes:
forming a conductive layer to fill up the opening; and
removing the conductive layer until a top surface of the structure is exposed.

32. The method of claim 31, further comprising forming a spacer on a side surface of the gate electrode by etching the structure.

33. The method of claim 32, further comprising implanting impurities on surface portions of the substrate that is exposed during the etching process on the structure to thereby form doped regions on the substrate.

34. The method of claim 33, further comprising forming a metal silicide layer on the gate electrode and the doped regions.

35. The method of claim 31, wherein the gate electrode includes a polysilicon layer doped with impurities.

36. The method of claim 35, further comprising a metal silicide layer on the polysilicon layer.

37. A method of fabricating a semiconductor device, comprising:
forming a channel layer on a surface of a substrate;
forming a single crystalline silicon layer on the channel layer;
forming a gate insulation layer by thermally oxidizing the single crystalline silicon layer;
forming a gate electrode on the gate insulation layer; and
forming source/drain regions on the substrate facing each other with respect to the gate electrode.

38. The method of claim 37, further comprising:
forming a fin body protruded from the substrate and extending in a first direction; and
forming a structure on the substrate including the fin body in a second direction substantially perpendicular to the first direction, the fin body being partially exposed through an opening of the structure,
wherein the channel layer is formed on a surface of the fin body that is exposed in the opening.

39. The method of claim 38, further comprising forming a capping pattern on the fin body, wherein the channel layer is formed on a portion of a side surface of the fin body.

40. The method of claim 37, further comprising forming a fin body protruded from a substrate and extending substantially parallel with the substrate, wherein the channel layer is formed on a surface of the fin body.

41. The method of claim 40, wherein forming the gate electrode includes:
forming a conductive layer on the fin body to cover the gate insulation layer; and
patterning the conductive layer.

42. The method of claim 37, further comprising forming a structure extending substantially parallel with the substrate, a surface of the substrate being partially exposed through an opening of the structure, wherein the channel layer is formed on the surface of the substrate within the opening.
